(19) United States
(12) Patent Application Publication
(10) Pub. No.: US 2025/0158627 A1
(43) Pub. Date: May 15, 2025

(54) HIGH-SPEED AND HIGH-PRECISION ANALOG-TO-DIGITAL CONVERTER AND ANALOG-TO-DIGITAL CONVERTER PERFORMANCE IMPROVEMENT METHOD

(71) Applicants: Chongqing GigaChip Technology Co., Ltd., Chongqing (CN); NO.24 RESEARCH INSTITUTE OF CHINA ELECTRONICS TECHNOLOGY GROUP CORPORATION, Chongqing (CN)

(72) Inventors: Ting LI, Chongqing (CN); Ruzhang LI, Chongqing (CN); Yong ZHANG, Chongqing (CN); Yabo NI, Chongqing (CN); Liang LI, Chongqing (CN); Dongbing FU, Chongqing (CN); Jianan WANG, Chongqing (CN); Guangbing CHEN, Chongqing (CN)

(73) Assignees: Chongqing GigaChip Technology Co., Ltd., Chongqing (CN); NO.24 RESEARCH INSTITUTE OF CHINA ELECTRONICS TECHNOLOGY GROUP CORPORATION, Chongqing (CN)

(21) Appl. No.: 19/026,465

(22) Filed: Jan. 17, 2025

Related U.S. Application Data
(63) Continuation of application No. PCT/CN2023/074200, filed on Feb. 2, 2023.
(63) Continuation of application No. PCT/CN2023/096787, filed on May 29, 2023.

(30) Foreign Application Priority Data
Dec. 31, 2022 (CN) 202211735360.7
Dec. 31, 2022 (CN) 202211739280.9
Feb. 2, 2023 (WO) PCT/CN2023/074200
May 29, 2023 (WO) PCT/CN2023/096787

(51) Int. Cl. H03M 1/10; H03M 1/06

(52) U.S. Cl. CPC H03M 1/1014; H03M 1/0604

(57) ABSTRACT

An analog-to-digital converter includes an input configuration module, an analog-to-digital conversion module, an adaptive parameter extraction module, and a full-period data restoration module. In a parameter extraction working mode, correction parameters are extracted through cooperation of the input configuration module, the analog-to-digital conversion module, the adaptive parameter extraction module, and the full-period data restoration module. In a normal working mode, digital calibration and correction of digital signals are implemented by using the analog-to-digital conversion module and the correction parameters. The correction parameters include a dither correction parameter, a gain correction parameter, and a mismatch error correction parameter.

### CROSS REFERENCE TO RELATED APPLICATION

The present application is a continuation application of PCT Application No. PCT/CN2023/074200 filed on Feb. 2, 2023, and a continuation application of PCT Application No. PCT/CN2023/096787, filed on May 29, 2023; PCT/CN2023/074200 claiming the benefit of priority to a Chinese Patent Application number CN202211739280.9, filed on Dec. 31, 2022, and PCT/CN2023/096787 claiming the benefit of priority to a Chinese Patent Application number CN 202211735360.7, filed on Dec. 31, 2022, each disclosure of the above applications is hereby incorporated by reference in its entirety for all purposes.

### TECHNICAL FIELD

The present disclosure relates to the field of integrated circuit technologies, and in particular, to a high-speed and high-precision analog-to-digital converter and an analog-to-digital converter performance improvement method.

### BACKGROUND

An analog-to-digital converter is an electronic component that converts an analog signal into a digital signal. Quality of signal collection and conversion depends on a speed and precision of the analog-to-digital converter. With development of information technology, a requirement for signal collection and conversion is increasingly high, and a high-speed and high-precision analog-to-digital converter is a hotspot required by an integrated system.

### SUMMARY

One or more embodiments of the present disclosure provide a high-speed and high-precision analog-to-digital converter technical solution, to resolve problems of a decrease in a signal-to-noise ratio and reduction of linearity that are caused by a process deviation and an insufficient component intrinsic gain, and a problem of a decrease in the signal-to-noise ratio that is caused by dither injection.

To achieve the foregoing objective and other related objectives, the present disclosure provides the following technical solutions.

A high-speed and high-precision analog-to-digital converter is provided, and includes an input configuration module, an analog-to-digital conversion module, an adaptive parameter extraction module, and a full-period data restoration module.

The adaptive parameter extraction module sends a configuration control signal to the input configuration module, and the input configuration module configures and generates an analog signal, quantization control signals, and an output mode control signal under the control of the configuration control signal.

The analog-to-digital conversion module receives the analog signal, the quantization control signals, and the output mode control signal, performs analog-to-digital conversion on the analog signal to obtain digital signals, and under the control of the quantization control signals and the output mode control signal, rearranges the digital signals when the high-speed and high-precision analog-to-digital converter is in a parameter extraction working mode to obtain rearranged digital signals, and calibrates the digital signals based on correction parameters when the high-speed and high-precision analog-to-digital converter is in a normal working mode to obtain corrected digital signals.

The adaptive parameter extraction module sends output data mode information to the full-period data restoration module, and the full-period data restoration module receives the output data mode information and the rearranged digital signals, and restores the rearranged digital signals to full-period data based on the output data mode information, to obtain and output full-period rearranged digital signals.

The adaptive parameter extraction module receives the full-period rearranged digital signals, extracts the correction parameters from the full-period rearranged digital signals by using an adaptive parameter extraction method, and then sends the correction parameters to a parameter memory inside the analog-to-digital converter for storage.

The correction parameters include at least a dither correction parameter, a gain correction parameter, and a mismatch error correction parameter.

In an embodiment, the analog-to-digital conversion module includes a first operation circuit, n stages of quantization circuits cascaded in sequence, n random number generation circuits, and n analog random signal generation circuits, the n random number generation circuits are connected to the n analog random signal generation circuits in a one-to-one correspondence, the random number generation circuit generates a random digital signal, and the analog random signal generation circuit performs digital-to-analog conversion on the random digital signal to obtain a random analog signal; a first input terminal of the first operation circuit is connected to the analog signal, a second input terminal of the first operation circuit is connected to a first random analog signal, an output terminal of the first operation circuit is connected to an analog input terminal of a first stage of quantization circuit, and the first operation circuit performs an additive operation on the analog signal and the first random analog signal; a feedback adjustment input terminal of the first stage of quantization circuit is connected to a second random analog signal, a control input terminal of the first stage of quantization circuit is connected to a first quantization control signal, an analog output terminal of the first stage of quantization circuit is connected to an analog input terminal of a second stage of quantization circuit, and a digital output terminal of the first stage of quantization circuit outputs a first stage of digital signal; a feedback adjustment input terminal of an i^{th} stage of quantization circuit is connected to an (i+1)^{th} random analog signal, a control input terminal of the i^{th} stage of quantization circuit is connected to an i^{th} quantization control signal, an analog output terminal of the i^{th} stage of quantization circuit is connected to an analog input terminal of an (i+1)^{th} stage of quantization circuit, and a digital output terminal of the i^{th} stage of quantization circuit outputs an i^{th} stage of digital signal; a digital output terminal of an n^{th} stage of quantization circuit outputs an n^{th} stage of digital signal; and n is an integer greater than or equal to 2, and i is an integer of 2 to n−1.

In an embodiment, a j^{th} stage of quantization circuit includes an analog-to-digital sub-converter and a multiplication digital-to-analog converter, an analog input terminal of the analog-to-digital sub-converter serves as an analog input terminal of the j^{th} stage of quantization circuit, the analog-to-digital sub-converter is connected to an analog input signal and performs analog-to-digital conversion on the analog input signal to obtain a digital output signal, and a digital output terminal of the analog-to-digital sub-converter serves as a digital output terminal of the j^{th} stage of quantization circuit; the multiplication digital-to-analog converter includes a digital-to-analog sub-converter, a second operation circuit, and an amplifier, the digital-to-analog sub-converter is connected to the digital output signal and performs digital-to-analog conversion on the digital output signal to obtain an analog output signal, a first input terminal of the second operation circuit is connected to the analog input terminal of the analog-to-digital sub-converter, a second input terminal of the second operation circuit is connected to the analog output signal, a third input terminal of the second operation circuit serves as a feedback adjustment input terminal of the j^{th} stage of quantization circuit, the third input terminal of the second operation circuit is connected to the random analog signal, an output terminal of the second operation circuit is connected to an input terminal of the amplifier, and the second operation circuit performs an operation of “the analog input signal−the analog output signal+the random analog signal”; an output terminal of the amplifier serves as an analog output terminal of the j^{th} stage of quantization circuit; and j is an integer of 1 to n−1.

In an embodiment, the n^{th} stage of quantization circuit includes an analog-to-digital sub-converter, an analog input terminal of the analog-to-digital sub-converter serves as an analog input terminal of the n^{th} stage of quantization circuit, the analog-to-digital sub-converter is connected to an analog input signal and performs analog-to-digital conversion on the analog input signal to obtain a digital output signal, and a digital output terminal of the analog-to-digital sub-converter serves as a digital output terminal of the n^{th} stage of quantization circuit.

In an embodiment, the analog-to-digital conversion module further includes a data alignment unit, and the data alignment unit receives n random digital signals and n stages of digital signals, and performs alignment processing on a random digital signal and a digital signal of each stage of quantization circuit.

In an embodiment, the analog-to-digital conversion module further includes a data rearrangement unit, and the data rearrangement unit is connected to the output mode control signal and the aligned n random digital signals and n stages of digital signals, rearranges, under the control of the output mode control signal when the high-speed and high-precision analog-to-digital converter is in the parameter extraction working mode, the n random digital signals and the n stages of digital signals that are obtained after one-time sampling and alignment, to obtain the rearranged digital signals, and outputs the rearranged digital signals in batches.

In an embodiment, the analog-to-digital conversion module further includes a digital calibration unit, the digital calibration unit is separately connected to the data alignment unit and the parameter memory, and when the high-speed and high-precision analog-to-digital converter is in the normal working mode, the digital calibration unit calibrates and corrects, based on the correction parameters stored in the parameter memory, the n random digital signals and the n stages of digital signals that are obtained after one-time sampling and alignment, to obtain the corrected digital signals.

In an embodiment, the analog-to-digital conversion module further includes an output interface unit, and the output interface unit is separately connected to the data rearrangement unit, the digital calibration unit, and the full-period data restoration module; when the high-speed and high-precision analog-to-digital converter is in the parameter extraction working mode, the output interface unit receives the rearranged digital signals and sends the rearranged digital signals to the full-period data restoration module in batches; and when the high-speed and high-precision analog-to-digital converter is in the normal working mode, the output interface unit receives the corrected digital signals and outputs the corrected digital signals.

In an embodiment, the parameter memory includes:
a soft correction parameter storage unit, configured to receive and store, at one single time, the correction parameters extracted by the adaptive parameter extraction module, and send the correction parameters to the digital calibration unit for digital calibration; and
a hard correction parameter storage unit, where after the correction parameters output by the soft correction parameter storage unit are qualified, the correction parameters stored in the soft correction parameter storage unit are sent to the hard correction parameter storage unit and solidified, so that the correction parameters are stored in the hard correction parameter storage unit for a long time, and when a system is powered on again after being powered off, the soft correction parameter storage unit reads, at one single time, the correction parameters stored in the hard correction parameter storage unit, and outputs the correction parameters.

In an embodiment, the dither correction parameter includes an actual weight of each random analog signal, the gain correction parameter includes an actual gain of each stage of quantization circuit, and the mismatch error correction parameter includes an actual weight of the digital-to-analog sub-converter in each stage of quantization circuit.

An analog-to-digital converter performance improvement method is provided, and includes:
providing an analog-to-digital converter, adding a random number generation circuit and an analog random signal generation circuit to the analog-to-digital converter, generating a plurality of random analog signals by using the random number generation circuit and the analog random signal generation circuit, and injecting dithers into the analog-to-digital converter by using the plurality of random analog signals;
adding an input configuration module, a data rearrangement unit, a full-period data restoration module, and an adaptive parameter extraction module to the analog-to-digital converter, and extracting correction parameters of each stage of quantization circuit in the analog-to-digital converter through cooperation of the input configuration module, the data rearrangement unit, the full-period data restoration module, and the adaptive parameter extraction module;
adding a parameter memory to the analog-to-digital converter, and storing the correction parameters by using the parameter memory, where the parameter memory performs one-time storage on the correction parameters in a test extraction phase, and the parameter memory performs solidification storage on the correction parameters after a test passes; and
adding a digital calibration unit to the analog-to-digital converter, and calibrating and correcting, in the digital calibration unit based on the correction parameters stored in the parameter memory, digital signals obtained through analog-to-digital conversion of the analog-to-digital converter, to obtain corrected digital signals for implementing digital calibration.

The correction parameters include at least a dither correction parameter, a gain correction parameter, and a mismatch error correction parameter.

In an embodiment, extracting correction parameters of each stage of quantization circuit in the analog-to-digital converter through cooperation of the input configuration module, the data rearrangement unit, the full-period data restoration module, and the adaptive parameter extraction module includes:
the adaptive parameter extraction module sends a configuration control signal to the input configuration module, and the input configuration module configures and generates an analog signal, quantization control signals, and an output mode control signal under the control of the configuration control signal;
the analog-to-digital conversion module receives the analog signal, the quantization control signals, and the output mode control signal, performs analog-to-digital conversion on the analog signal under the control of the quantization control signals to obtain digital signals, rearranges the digital signals under the control of the output mode control signal to obtain rearranged digital signals, and sends all rearranged digital signals to the full-period data restoration module through outputting in batches;
the adaptive parameter extraction module sends output data mode information to the full-period data restoration module, and the full-period data restoration module receives the output data mode information and the rearranged digital signals, and restores the rearranged digital signals to full-period data based on the output data mode information, to obtain and output full-period rearranged digital signals; and
the adaptive parameter extraction module receives the full-period rearranged digital signals, and extracts the correction parameters from the full-period rearranged digital signals by using an adaptive parameter extraction method.

### BRIEF DESCRIPTION OF DRAWINGS

FIG. 1 is a block diagram of a structure of a high-speed and high-precision analog-to-digital converter according to at least one embodiment of the present disclosure;

FIG. 2 is a diagram of a circuit structure of first n−1 stages of quantization circuits according to an optional embodiment of the present disclosure;

FIG. 3 is a diagram of a circuit structure of an n^{th} stage of quantization circuit according to an optional embodiment of the present disclosure;

FIG. 4 is a schematic diagram of an adaptive parameter extraction method of an analog-to-digital converter according to at least one embodiment of the present disclosure;

FIG. 5 is a flowchart of extracting gain correction parameters and the mismatch error correction parameters of all the conversion stages of an analog-to-digital converter according to at least one embodiment of the present disclosure;

FIG. 6 is a flowchart of calculating gain correction parameters and mismatch error correction parameters of all the conversion stages of an analog-to-digital converter according to at least one embodiment of the present disclosure;

FIG. 7 is a block diagram of a structure of a parameter memory 8 according to an optional embodiment of the present disclosure; and

FIG. 8 is a schematic diagram of an analog-to-digital converter performance improvement method according to at least one embodiment of the present disclosure.

FIG. 9 is another schematic diagram of an analog-to-digital converter performance improvement method according to at least one embodiment of the present disclosure.

### DESCRIPTION OF EMBODIMENTS

The inventors find, through research, that, with high-speed and high-precision development of an analog-to-digital converter, progress of a manufacturing process leads to a decrease in a signal-to-noise ratio and reduction of linearity of the analog-to-digital converter while bringing about an increase in a speed, and there are shortcomings in at least the following aspects:
(1) With reduction of a process size, a size of a component is increasingly small, and a mismatch error of the component is increasingly large, resulting in a decrease in a signal-to-noise ratio and reduction of linearity of an analog-to-digital converter.
(2) With the reduction of the process size, an intrinsic gain of the component is increasingly small, and a gain of an operational amplifier hardly meets a precision requirement of the analog-to-digital converter. This further results in a decrease in the signal-to-noise ratio and reduction of linearity of the analog-to-digital conversion.
(3) In a conventional manner of injecting a random dither signal, conversion linearity of the analog-to-digital converter can be improved. However, because of a component process deviation, an injected random dither usually cannot be completely eliminated, decreasing a signal-to-noise ratio of the analog-to-digital converter while improving linearity.

Therefore, currently, a technical solution of a high-speed and high-precision analog-to-digital converter is required, to resolve problems of a decrease in a signal-to-noise ratio and reduction of linearity of the analog-to-digital converter that are caused by a process deviation and an insufficient component intrinsic gain, and a problem of a decrease in the signal-to-noise ratio that is caused by dither injection.

Based on this, the present disclosure provides a high-speed and high-precision analog-to-digital converter technical solution: A dither generation structure is added to an analog-to-digital converter, to generate a plurality of random analog signals by using the dither generation structure, and inject dithers into the analog-to-digital converter, thereby improving linearity of the analog-to-digital converter. A correction parameter extraction structure is added to the analog-to-digital converter, to extract correction parameters of each stage of quantization circuit in the analog-to-digital converter by using the correction parameter extraction structure. The correction parameters include at least a dither correction parameter, a gain correction parameter, and a mismatch error correction parameter. A parameter memory is added to the analog-to-digital converter, and the parameter memory combines one-time storage and solidification storage to improve storage efficiency. A digital calibration unit is added to the analog-to-digital converter, and the digital calibration unit calibrates and corrects, with reference to the correction parameters, digital signals obtained through analog-to-digital conversion of the analog-to-digital converter, to implement digital calibration, thereby preventing performance of the analog-to-digital converter from being affected by an increasingly small intrinsic gain and an increasingly large mismatch error that are caused by reduction of a process size, and completely eliminating injected random dithers.

The following describes implementations of the present disclosure by using specific examples. A person skilled in the art can easily understand other advantages and effects of the present disclosure based on the content disclosed in this specification. The present disclosure may be further implemented or applied by using other different specific implementations. Various details in this specification may also be modified or altered based on different viewpoints and applications without departing from the present disclosure.

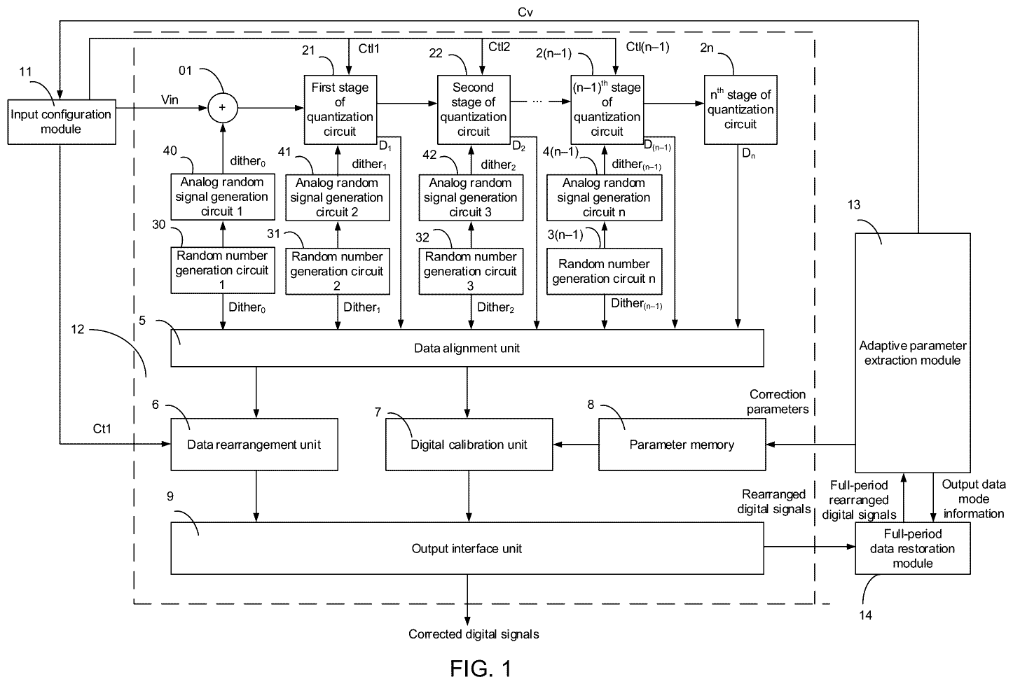

Refer to FIG. 1 to FIG. 9. It should be noted that the drawings provided in the embodiments merely describe the basic concept of the present disclosure by using examples. Although the drawings show only components related to the present disclosure, and are not drawn based on a quantity of components, a shape of a component, and a size of a component during actual implementation, a shape, a quantity, and a scale of the components may be arbitrarily changed during actual implementation, and a component layout form may be more complex. The structure, scale, size, and the like shown in the drawings of this specification are merely used to cooperate with the content disclosed in this specification for a person skilled in the art to understand and read, and are not restrictions for limiting implementation of the present disclosure, and therefore have no technically substantial significance. Any modification of the structure, change of a proportional relationship, or adjustment of the size shall still fall within the scope that can be covered by the technical content disclosed in the present disclosure, provided that they do not affect the efficacy that can be generated by the present disclosure and the purpose that can be achieved by the present disclosure.

As shown in FIG. 1, the present disclosure provides a high-speed and high-precision analog-to-digital converter, including an input configuration module 11, an analog-to-digital conversion module 12, an adaptive parameter extraction module 13, and a full-period data restoration module 14.

The adaptive parameter extraction module 13 sends a configuration control signal Cv to the input configuration module 11. The input configuration module 11 configures and generates an analog signal Vin, quantization control signals Ctl1 to Ctl(n−1), and an output mode control signal Ct1 under the control of the configuration control signal Cv.

The analog-to-digital conversion module 12 receives the analog signal Vin, the quantization control signals Ctl1 to Ctl(n−1), and the output mode control signal Ct1, performs analog-to-digital conversion on the analog signal Vin to obtain digital signals D₁ to Dₙ, and under the control of the quantization control signals Ctl1 to Ctl(n−1) and the output mode control signal Ct1, rearranges the digital signals D₁ to Dₙ when the high-speed and high-precision analog-to-digital converter is in a parameter extraction working mode to obtain rearranged digital signals, and calibrates the digital signals based on correction parameters when the high-speed and high-precision analog-to-digital converter is in a normal working mode to obtain corrected digital signals.

The adaptive parameter extraction module 13 sends output data mode information to the full-period data restoration module 14, and the full-period data restoration module 14 receives the output data mode information and the rearranged digital signals, and restores the rearranged digital signals to full-period data based on the output data mode information, to obtain and output full-period rearranged digital signals.

The adaptive parameter extraction module 13 receives the full-period rearranged digital signals, extracts the correction parameters from the full-period rearranged digital signals by using an adaptive parameter extraction method, and then sends the correction parameters to a parameter memory 8 inside the analog-to-digital converter 12 for storage.

The correction parameters include at least a dither correction parameter, a gain correction parameter, and a mismatch error correction parameter.

In detail, as shown in FIG. 1, the analog-to-digital conversion module 12 includes a first operation circuit 01, n stages of quantization circuits 21 to 2n cascaded in sequence, n random number generation circuits 30 to 3(n−1), and n analog random signal generation circuits 40 to 4(n−1). The n random number generation circuits 30 to 3(n−1) are connected to the n analog random signal generation circuits 40 to 4(n−1) in a one-to-one correspondence. A random number generation circuit 3k generates a random digital signal Ditherₖ, and an analog random signal generation circuit 4k performs digital-to-analog conversion on the random digital signal Ditherₖ to obtain a random analog signal ditherₖ. A first input terminal of the first operation circuit 01 is connected to the analog signal Vin, a second input terminal of the first operation circuit 01 is connected to a first random analog signal dither₀, an output terminal of the first operation circuit 01 is connected to an analog input terminal of a first stage of quantization circuit 21, and the first operation circuit 01 performs an additive operation on the analog signal Vin and the random analog signal dither₀. A feedback adjustment input terminal of the first stage of quantization circuit 21 is connected to a second random analog signal dither₁, a control input terminal of the first stage of quantization circuit 21 is connected to a first quantization control signal Ctl1, an analog output terminal of the first stage of quantization circuit 21 is connected to an analog input terminal of a second stage of quantization circuit 22, and a digital output terminal of the first stage of quantization circuit 21 outputs a first stage of digital signal D₁. A feedback adjustment input terminal of an i^{th} stage of quantization circuit 2i is connected to an (i+1)^{th} random analog signal ditherᵢ, a control input terminal of the i^{th} stage of quantization circuit 2i is connected to an i^{th} quantization control signal Ctli, an analog output terminal of the i^{th} stage of quantization circuit 2i is connected to an analog input terminal of an (i+1)^{th} stage of quantization circuit 2(i+1), and a digital output terminal of the i^{th} stage of quantization circuit 2i outputs an i^{th} stage of digital signal Dᵢ. A digital output terminal of an n^{th} stage of quantization circuit 2n outputs an n^{th} stage of digital signal Dₙ. n is an integer greater than or equal to 2, k is a natural number of 0 to n−1, and i is an integer of 2 to n−1.

In more detail, as shown in FIG. 1, the n random number generation circuits 30 to 3(n−1) are connected to the n analog random signal generation circuits 40 to 4(n−1) in a one-to-one correspondence, that is, a random number generation circuit 30 is connected to an analog random signal generation circuit 40, a random number generation circuit 31 is connected to an analog random signal generation circuit 41, a random number generation circuit 32 is connected to an analog random signal generation circuit 42, . . . , and a random number generation circuit 3(n−1) is connected to an analog random signal generation circuit 4(n−1).

The k^{th} stage of random number generation circuit 3k is configured to generate the random integral random digital signal Ditherₖ, where the signal may be generated or not generated according to a system requirement. The k^{th} stage of analog random signal generation circuit 4k is configured to convert the input random digital signal Ditherₖ into the corresponding analog random signal ditherₖ for output, where the signal may be generated or not generated according to a system requirement.

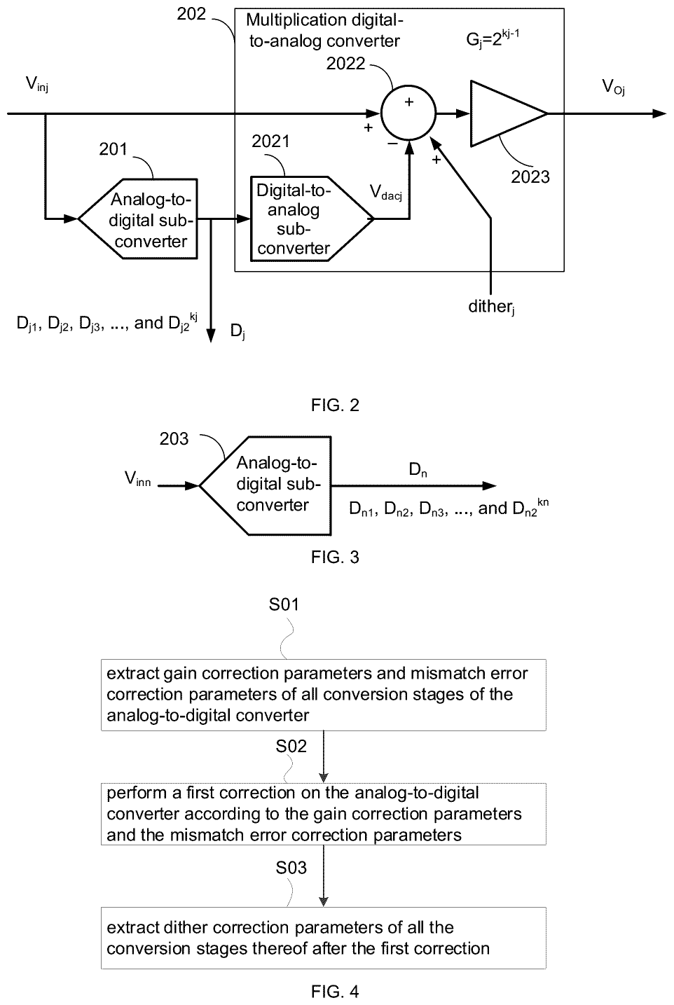

In more detail, as shown in FIG. 2, in an optional embodiment of the present disclosure, a j^{th} stage of quantization circuit 2j includes an analog-to-digital sub-converter 201 and a multiplication digital-to-analog converter 202. An analog input terminal of the analog-to-digital sub-converter 201 serves as an analog input terminal of the j^{th} stage of quantization circuit 2j, the analog-to-digital sub-converter 201 is connected to an analog input signal Vᵢₙⱼ and performs analog-to-digital conversion on the analog input signal Vᵢₙⱼ, to obtain a digital output signal Dⱼ, and a digital output terminal of the analog-to-digital sub-converter 201 serves as a digital output terminal of the j^{th} stage of quantization circuit. The multiplication digital-to-analog converter 202 includes a digital-to-analog sub-converter 2021, a second operation circuit 2022, and an amplifier 2023. The digital-to-analog sub-converter 2021 is connected to the digital output signal Dⱼ and performs digital-to-analog conversion on the digital output signal Dⱼ, to obtain an analog output signal V_{dacj}, a first input terminal of the second operation circuit 2022 is connected to the analog input terminal of the analog-to-digital sub-converter 201, a second input terminal of the second operation circuit 2022 is connected to the analog output signal V_{dacj}, a third input terminal of the second operation circuit 2022 serves as a feedback adjustment input terminal of the j^{th} stage of quantization circuit 2j, the third input terminal of the second operation circuit 2022 is connected to a random analog signal ditherⱼ, an output terminal of the second operation circuit 2022 is connected to an input terminal of the amplifier 2023, and the second operation circuit 2022 performs an operation of “the analog input signal Vᵢₙⱼ−the analog output signal V_{dacj}+the random analog signal ditherⱼ”. An output terminal of the amplifier 2023 serves as an analog output terminal of the j^{th} stage of quantization circuit 2j, and the amplifier 2023 amplifies an output of the second operation circuit 2022 by Gj times to obtain an output V_{Oj} of the j^{th} stage of quantization circuit 2j, where j is an integer of 1 to n−1.

Bit of the analog-to-digital sub-converter 201 is the same as the bit of the digital-to-analog sub-converter 2021, for example, both kj-bit, kj-bit analog-to-digital sub-converter 201 and kj-bit digital-to-analog sub-converter 2021. The digital output signal Dⱼ generated has kj bits, Dⱼ₁, Dⱼ₂, Dⱼ₃, . . . , and Dⱼ₂^{kj}. A gain of the amplifier 2023 is usually Gⱼ=2^{kj-1}, and may be adjusted under the control of Ctlj.

In more detail, as shown in FIG. 3, in an optional embodiment of the present disclosure, the n^{th} stage of quantization circuit 2n includes an analog-to-digital sub-converter 203. An analog input terminal of the analog-to-digital sub-converter 203 serves as an analog input terminal of the n^{th} stage of quantization circuit 2n, the analog-to-digital sub-converter 203 is connected to an analog input signal Vᵢₙₙ and performs analog-to-digital conversion on the analog input signal Vᵢₙₙ, to obtain a digital output signal Dₙ, and a digital output terminal of the analog-to-digital sub-converter 203 serves as a digital output terminal of the n^{th} stage of quantization circuit 2n. No dither signal is added to the n^{th} stage of quantization circuit 2n.

A quantity of bits of the analog-to-digital sub-converter 203 may be set as required. This is not limited herein. For example, a quantity of bits of the analog-to-digital sub-converter 203 is kn, the digital output signal Dₙ generated by the kn-bits analog-to-digital sub-converter 203 has kn bits, Dₙ₁, Dₙ₂, Dₙ₃, . . . , and Dₙ₂^{kn}.

It should be noted that when the high-speed and high-precision analog-to-digital converter is in the parameter extraction working mode, for correction parameter extraction of an m^{th} stage of quantization circuit 2m, an amplitude of an analog output signal of an (m−1)^{th} stage of quantization circuit 2(m−1) is increased (for example, by two times) through control and adjustment of the quantization control signals Ctl1 to Ctl(m−1), so that expected application ranges are traversed for correction parameter extraction of the m^{th} stage of quantization circuit 2m, where m is an integer of 2 to n. The input configuration module 11 configures a required input signal amplitude for correction parameter extraction of the first stage of quantization circuit 21. Details are not described herein.

As shown in FIG. 4, the adaptive parameter extraction method includes:
S01: extract gain correction parameters and mismatch error correction parameters of all conversion stages of the analog-to-digital converter;
S02: perform a first correction on the analog-to-digital converter according to the gain correction parameters and the mismatch error correction parameters; and
S03: extract dither correction parameters of all the conversion stages thereof after the first correction.

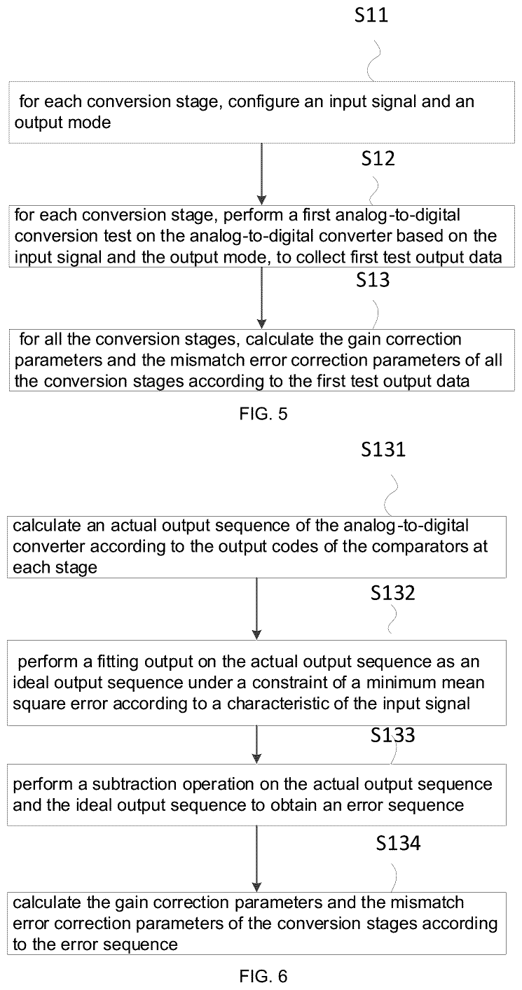

In details, in an optional embodiment of the present disclosure, as shown in FIG. 5, the step S01 of extracting the gain correction parameters and the mismatch error correction parameters of all the conversion stages of an analog-to-digital converter further includes:
S11: for each conversion stage, configure an input signal and an output mode;
S12: for each conversion stage, perform a first analog-to-digital conversion test on the analog-to-digital converter based on the input signal and the output mode, to collect first test output data; and
S13: for all the conversion stages, calculate the gain correction parameters and the mismatch error correction parameters of all the conversion stages according to the first test output data.

In more details, step S11 of configuring the input signal and the output mode includes: configuring an amplitude of the input signal of each stage and a threshold voltage of comparators at each stage, and configuring an output interface to send all output results of the comparators at each stage.

The analog-to-digital converter includes n conversion stages; when a gain correction parameter and a mismatch error correction parameter of the i^{th} conversion stage are extracted, a maximum value of the input signal of the i^{th} stage is greater than the maximum comparator threshold of the i^{th} conversion stage, and a minimum value of the input signal of the i^{th} stage is smaller than the minimum comparator threshold of the i^{th} conversion stage, for example, an input signal that is 1 dB less than a full amplitude is usually input; when i≥2, a threshold voltage of comparators at a pre-stage is configured so that the signal amplitude always does not exceed a comparator threshold thereof, and the input signal reaches the approximately full amplitude when the input signal is transmitted to the i^{th} stage, wherein n is an integer greater than or equal to 2, and i is an integer of 1−n.

In more details, in the step S12, output data are collected, and the amount of the collected data is usually several thousands of data points. The data amount may be increased or decreased according to the precision of the analog-to-digital converter, which is not limited herein.

As shown in FIG. 5, in an optional embodiment of the present disclosure, before the gain correction parameters and the mismatch error correction parameters of all the conversion stages of the analog-to-digital converter are calculated and extracted, it needs to be further determined whether collection of data of each stage is completed, which partially corresponds to step S13. If the collection of data that needs to be corrected at each stage is completed, it goes to a next step, otherwise, returns to step S11, that is, an input signal is set and an output mode is configured based on an error that needs to be extracted.

Specifically, in an optional embodiment of the present disclosure, as shown in FIG. 6, the first test output data includes at least the output codes of the comparators at each stage, and the step S13 of calculating the gain correction parameters and the mismatch error correction parameters of all the conversion stages according to the first test output data further includes:
S131: calculate an actual output sequence of the analog-to-digital converter according to the output codes of the comparators at each stage;
S132: perform a fitting output on the actual output sequence as an ideal output sequence under a constraint of a minimum mean square error according to a characteristic of the input signal;
S133: perform a subtraction operation on the actual output sequence and the ideal output sequence to obtain an error sequence; and
S134: calculate the gain correction parameters and the mismatch error correction parameters of the conversion stages according to the error sequence.

In more details, in the step S131, the actual output sequence of the analog-to-digital converter is obtained based on the output codes of the comparators at each stage:

$${D}_{out} ( m ) = {W}_{ij \_ ideal} {d}_{ij} ( m ) ;$$

wherein dᵢⱼ(m) represents an output code of the j^{th} comparator at the i^{th} stage, W_{ij_ideal} represents an ideal weight of the j^{th} quantization unit at the i^{th} stage, and Dₒᵤₜ(m) represents an actual output sequence of the analog-to-digital converter obtained according to the output of the comparator.

In more detail, in the step S132, a fitting output sequence \hat{D}ₒᵤₜ(m) is obtained as an ideal output sequence under a constraint of a minimum mean square error based on a characteristic of the input signal and the actual output sequence.

In more detail, in the step S133, an error sequence is obtained according to the actual output sequence and the ideal output sequence:

$$err ( m ) = {D}_{out} ( m ) - {\hat{D}}_{out} ( m ) ;$$

wherein err(m) represents an error sequence.

In more detail, in the step S134, the actual inter-stage gain (namely, the gain correction parameter) and the actual weight (namely, the mismatch error correction parameter) of each quantization unit are calculated based on the error sequence, and the calculation formulas for the gain correction parameter and the mismatch error correction parameter are respectively as follows:

$${G}_{i} ( m + 1 ) = {G}_{i} ( m ) - {μ}_{igk} \frac{{D}_{ires} ( m )}{{2}^{N}} err ( m ) ;$$

$${W}_{ij} ( m + 1 ) = {W}_{ij} ( m ) - {μ}_{iwk} \frac{{d}_{ij} ( m ) {W}_{ij \_ ideal}}{{2}^{N}} err ( m ) ;$$

wherein Gᵢ(m) represents the m^{th} iteration value of the gain correction parameter of the i^{th} conversion stage, Dᵢᵣₑₛ(m) represents the m^{th} iteration value of a residual error of the i^{th} stage, μ_{igk} represents the k^{th} iteration step size of a gain of the i^{th} stage, Wᵢⱼ(m) represents the m^{th} iteration value of a weight of the j^{th} quantization unit at the i^{th} stage, dᵢⱼ(m) represents the m^{th} comparator output corresponding to the weight of the j^{th} quantization unit at the i^{th} stage, μ_{iwk} represents the k^{th} iteration step size of a weight of quantization units at the i^{th} stage, W_{ij_ideal} represents an ideal weight of the j^{th} quantization unit at the i^{th} stage.

The above iteration takes a form of a variable step size, and both of the iteration step sizes μ_{igk} and μ_{iwk} are selected in a descending order, so as to increase a convergence speed thereof.

In detail, in the step S02, the first correction is performed on the analog-to-digital converter according to the gain correction parameters and the mismatch error correction parameters, and a calculation formula for performing the first correction on the analog-to-digital converter is as follows:

$${D}_{out \_ cal} = {\sum }_{j = 1}^{{2}^{{k}_{1}}} {d}_{1 j} \cdot {W}_{1 j} + {\sum }_{j = 1}^{{2}^{{k}_{2}}} {d}_{2 j} \cdot {W}_{2 j} \cdot {\prod }_{i = 1}^{1} {G}_{i} + {\sum }_{j = 1}^{{2}^{{k}_{3}}} {d}_{3 j} \cdot {W}_{3 j} \cdot {\prod }_{i = 1}^{2} {G}_{i} + … + {\sum }_{j = 1}^{{2}^{{k}_{n}}} {d}_{nj} \cdot {W}_{nj} {\prod }_{i = 1}^{n - 1} {G}_{i} ;$$

wherein D_{out_cal} represents a digital output code after the first correction and 2^{k}^{ᵢ} (i=1, 2, 3 . . . ) represents a quantity of the quantization units at the i^{th} stage.

In detail, the step S03 of extracting the dither correction parameters of all the conversion stages of the analog-to-digital converter after the first correction further includes:
S31: for each conversion stage, configure an input signal and an output mode;
S32: for each conversion stage, according to the input signal and the output mode, open and extract jitter digital codes of one stage each time, perform a second analog-to-digital conversion test on the analog-to-digital converter after the first correction and collect second test output data; and
S33: for all the conversion stages, calculate the dither correction parameters of all the conversion stages based on the jitter digital codes and the second test output data.

In more detail, in the step S31, the input signal and the output mode are configured based on a quantity of errors that need to be extracted, and when the dither correction parameters (namely, jitter weights) are extracted, the threshold voltages of the comparators at all stages are restored to a normal working state, and no special requirement is imposed on the input signal. When the dither correction parameters are extracted, the input signal is set to a predetermined threshold (a signal with a small amplitude) or the input signal is disabled, so as to increase a convergence speed thereof.

In more detail, in the step S32, the jitter digital codes of all stages are opened, and only the jitter digital codes (namely, jitter signals) of one stage are opened and extracted each time. In other words, the jitter digital codes of one stage are successively opened and extracted, and the order of opening and extracting the jitter digital codes of all stages is not limited.

In more detail, in the step S33, the dither correction parameters of all the conversion stages are calculated according to the jitter digital codes and the second test output data. A corresponding calculation formula is as follows:

$${W}_{d \_ ij} ( m + 1 ) = {W}_{d \_ ij} ( m ) - {μ}_{diwk} \cdot {dd}_{ij} ( m ) \cdot ( {W}_{d \_ ij} ( m ) \cdot {dd}_{ij} ( m ) - {D}_{out \_ cal} ( m ) ) ;$$

wherein W_{d_ij}(m) represents the m^{th} iteration of the j^{th} dither correction parameter of the i^{th} stage and μ_{diwk} represents the k^{th} iteration step size of the dither correction parameters of the i^{th} stage. The iteration takes a form of a variable step size (iteration step sizes are selected in a descending order).

After completion, the jitter signals of the current stage are disabled.

In detail, as shown in FIG. 1, the analog-to-digital conversion module 12 further includes a data alignment unit 5. The data alignment unit 5 receives n random digital signals Dither₀ to Dither₍ₙ₋₁₎ and n stages of digital signals D₁ to Dₙ, and performs alignment processing on a random digital signal and a digital signal of each stage of quantization circuit.

In more detail, as shown in FIG. 1, the data alignment unit 5 is configured to align stages of digital signals Dⱼ and random digital signals Ditherⱼ that correspond to a same input signal. If a conversion time for each stage is t_{c}, a relative delay time between the random digital signal Ditherⱼ and a random digital signal Dither₁ is (j−1)×t_{c}, and a relative delay time between the digital signal Dⱼ and the digital signal D₁ is (j−1)×t_{c}. A fixed delay time may alternatively be added as required, provided that the relative delay time is ensured.

In more detail, as shown in FIG. 1, the analog-to-digital conversion module 12 further includes a data rearrangement unit 6. The data rearrangement unit 6 is connected to the output mode control signal Ct1 and the aligned n random digital signals Dither₀ to Dither₍ₙ₋₁₎ and n stages of digital signals D₁ to Dₙ, rearranges, under the control of the output mode control signal Ct1 when the high-speed and high-precision analog-to-digital converter is in the parameter extraction working mode, the n random digital signals Dither₀ to Dither₍ₙ₋₁₎ and the n stages of digital signals D₁ to Dₙ that are obtained after one-time sampling and alignment, to obtain the rearranged digital signals, and outputs the rearranged digital signals in batches.

The data rearrangement unit 6 is used only in the parameter extraction working mode. Because a quantity of output data ports required in the normal working mode is less than a volume of data that needs to be sent out in the parameter extraction mode, to ensure that output data Ditherₖ and Dₖ that need to be used for parameter extraction are output as required, data obtained through one-time sampling needs to be rearranged, and then sent out from an output interface unit 9 in batches. All quantized intermediate parameters may be sent out as required in a manner of combining data rearrangement with multiple-time output without changing an output interface, thereby resolving a problem that a conventional analog-to-digital converter cannot send out all quantized intermediate parameters.

In more detail, as shown in FIG. 1, the analog-to-digital conversion module 12 further includes a digital calibration unit 7. The digital calibration unit 7 is separately connected to the data alignment unit 6 and the parameter memory 8. When the high-speed and high-precision analog-to-digital converter is in the normal working mode, the digital calibration unit 7 calibrates and corrects, based on the correction parameters stored in the parameter memory 8, the n random digital signals Dither₀ to Dither₍ₙ₋₁₎ and the n stages of digital signals D₁ to Dₙ that are obtained after one-time sampling and alignment, to obtain the corrected digital signals, and sends the corrected digital signals to the output interface unit 9.

In more detail, as shown in FIG. 1, the analog-to-digital conversion module 12 further includes an output interface unit 9. The output interface unit 9 is separately connected to the data rearrangement unit 6, the digital calibration unit 7, and the full-period data restoration module 14. When the high-speed and high-precision analog-to-digital converter is in the parameter extraction working mode, the output interface unit 9 receives the rearranged digital signals and sends the rearranged digital signals to the full-period data restoration module 14 in batches; and when the high-speed and high-precision analog-to-digital converter is in the normal working mode, the output interface unit 9 receives the corrected digital signals and outputs the corrected digital signals.

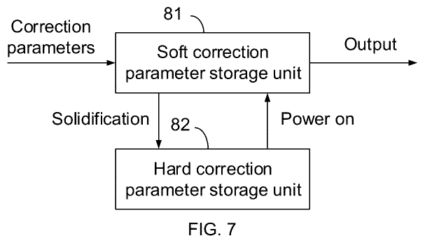

In more detail, as shown in FIG. 7, in an optional embodiment of the present disclosure, the parameter memory 8 further includes:
a soft correction parameter storage unit 81, configured to receive and store, at one single time, the correction parameters extracted by the adaptive parameter extraction module 13, and send the correction parameters to the digital calibration unit 7 for digital calibration; and
a hard correction parameter storage unit 82, where after the correction parameters output by the soft correction parameter storage unit 81 are qualified, the correction parameters stored in the soft correction parameter storage unit 81 are sent to the hard correction parameter storage unit 82 and solidified (here, solidified means that the correction parameters sent to and stored in hard correction parameter storage unit are fixed, and will not change later, even if it is powered off and then powered on), so that the correction parameters are stored in the hard correction parameter storage unit 82 for a long time, and when a system is powered on again after being powered off, the soft correction parameter storage unit 81 reads, at one single time, the correction parameters stored in the hard correction parameter storage unit 82, and outputs the correction parameters.

The parameter memory 8 can flexibly implement one-time storage in a test phase in a manner of combining one-time storage with solidification storage, and performing solidification storage after a test is completed effectively improves storage efficiency.

It should be noted that, when the high-speed and high-precision analog-to-digital converter is in the parameter extraction working mode, the correction parameters of each stage of quantization circuit are extracted stage by stage, to obtain a plurality of correction parameters of each stage of quantization circuit.

In more detail, the adaptive parameter extraction module 13 extracts the correction parameters from the full-period rearranged digital signals by using an adaptive parameter extraction method, where the correction parameters include at least a dither correction parameter, a gain correction parameter, and a mismatch error correction parameter. The dither correction parameter includes at least actual weights of the random analog signals dither₀ to dither₍ₙ₋₁₎, the gain correction parameter includes at least actual gains G_{1_real} to G_{n-1_real} of the stages of quantization circuits, and the mismatch error correction parameter includes at least actual weights W_{1_real} to W_{n_real} of the digital-to-analog sub-converters of the stages of quantization circuits.

In more detail, when the high-speed and high-precision analog-to-digital converter is in the parameter extraction working mode, the input configuration module 11, the data rearrangement unit 6 and the output interface unit 9 in the analog-to-digital conversion module 12, the adaptive parameter extraction module 13, and the full-period data restoration module 14 are combined into a correction parameter extraction structure, and the correction parameter extraction structure extracts the correction parameters of each stage of quantization circuit in the analog-to-digital conversion module 12. When the high-speed and high-precision analog-to-digital converter is in the normal working mode, the digital calibration unit 7 and the parameter memory 8 in the analog-to-digital conversion module 12 are combined into a correction structure, and the correction structure calibrates and corrects the digital signals obtained through analog-to-digital conversion of the analog-to-digital converter, to implement digital calibration. In addition, a dither signal may be or may not be added to each stage of quantization circuit of the analog-to-digital conversion module 12, to selectively improve linearity of the analog-to-digital conversion module 12.

The adaptive parameter extraction module 13 uses the adaptive parameter extraction method, which requires a small quantity of samples, thereby greatly reducing a computational amount of parameter extraction. Intermediate parameter output is combined with the adaptive parameter extraction method, to implement extraction of a plurality of correction parameters of a plurality of stages of the analog-to-digital converter, to resolve a problem that the conventional analog-to-digital converter cannot extract the plurality of correction parameters of the plurality of stages. Linearity of the analog-to-digital converter is improved by injecting dithers, and the extracted correction parameters include the dither correction parameter, so that the injected dithers can be precisely eliminated through dither correction in the digital calibration unit 7, thereby preventing imprecise dither elimination from decreasing a signal-to-noise ratio of the system. The digital calibration unit 7 uses a digital calibration manner that has higher error calibration precision compared with an analog calibration manner.

Based on an overall structural design of “the input configuration module+the analog-to-digital conversion module+the adaptive parameter extraction module+the full-period data restoration module”, when the high-speed and high-precision analog-to-digital converter is in the parameter extraction working mode, the correction parameters can be extracted through cooperation of the input configuration module, the analog-to-digital conversion module, the adaptive parameter extraction module, and the full-period data restoration module; and when the high-speed and high-precision analog-to-digital converter is in the normal working mode, digital calibration and correction of the digital signals obtained after digital-to-analog conversion are implemented by using the analog-to-digital conversion module and the correction parameters. The correction parameters include at least a dither correction parameter, a gain correction parameter, and a mismatch error correction parameter. Therefore, a signal-to-noise ratio of the analog-to-digital converter is effectively increased and linearity of the analog-to-digital converter is effectively improved, performance of the analog-to-digital converter is prevented from being affected by an increasingly small intrinsic gain and an increasingly large mismatch error that are caused by reduction of a process size, injected random dithers are completely eliminated, and the signal-to-noise ratio of the analog-to-digital converter is prevented from being affected by the injected random dithers. In addition, the adaptive parameter extraction module extracts the correction parameters by using the adaptive parameter extraction method, which requires a small quantity of samples, thereby greatly reducing a computational amount of parameter extraction. A calibration manner is digital calibration that has higher error calibration precision compared with an analog calibration manner while resolving problems of a decrease in the signal-to-noise ratio and reduction of linearity of the analog-to-digital converter that are caused by a process deviation and an insufficient component intrinsic gain.

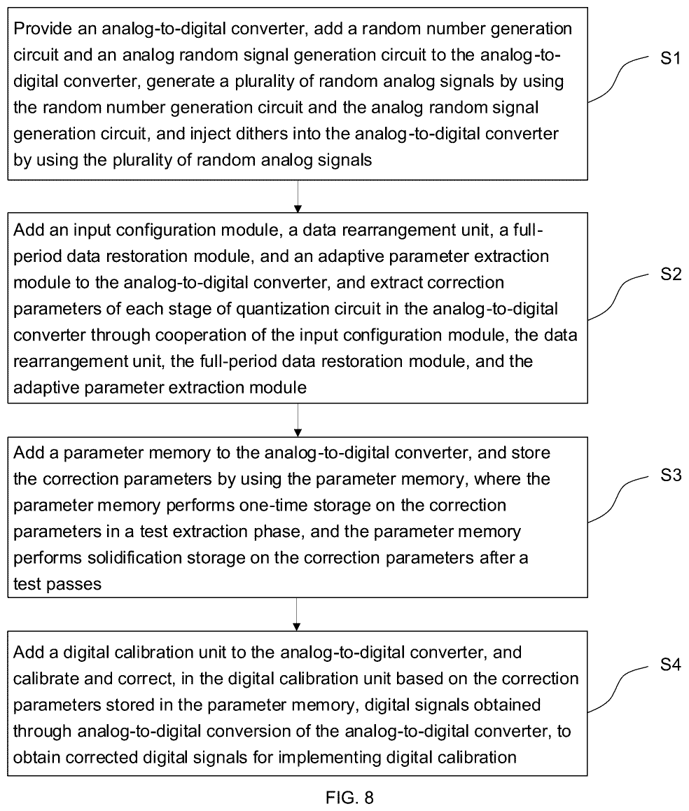

In addition, based on the foregoing design concept of the high-speed and high-precision analog-to-digital converter, the present disclosure further provides an analog-to-digital converter performance improvement method. As shown in FIG. 8, the method includes S1 to S4:
S1: Provide an analog-to-digital converter, add a random number generation circuit and an analog random signal generation circuit to the analog-to-digital converter, generate a plurality of random analog signals by using the random number generation circuit and the analog random signal generation circuit, and inject dithers into the analog-to-digital converter by using the plurality of random analog signals.
S2: Add an input configuration module, a data rearrangement unit, a full-period data restoration module, and an adaptive parameter extraction module to the analog-to-digital converter, and extract correction parameters of each stage of quantization circuit in the analog-to-digital converter through cooperation of the input configuration module, the data rearrangement unit, the full-period data restoration module, and the adaptive parameter extraction module.
S3: Add a parameter memory to the analog-to-digital converter, and store the correction parameters by using the parameter memory, where the parameter memory performs one-time storage on the correction parameters in a test extraction phase, and the parameter memory performs solidification storage on the correction parameters after a test passes.
S4: Add a digital calibration unit to the analog-to-digital converter, and calibrate and correct, in the digital calibration unit based on the correction parameters stored in the parameter memory, digital signals obtained through analog-to-digital conversion of the analog-to-digital converter, to obtain corrected digital signals for implementing digital calibration.

The correction parameters include at least a dither correction parameter, a gain correction parameter, and a mismatch error correction parameter.

In detail, in S1, the random number generation circuit and the analog random signal generation circuit form a dither generation structure, and the dither generation structure generates the plurality of random analog signals to inject the dithers into the analog-to-digital converter, thereby effectively improving linearity of the analog-to-digital converter. The dither generation structure may selectively inject dither signals (that is, the random analog signals) into some or all quantization stages in the analog-to-digital converter. This is not limited herein.

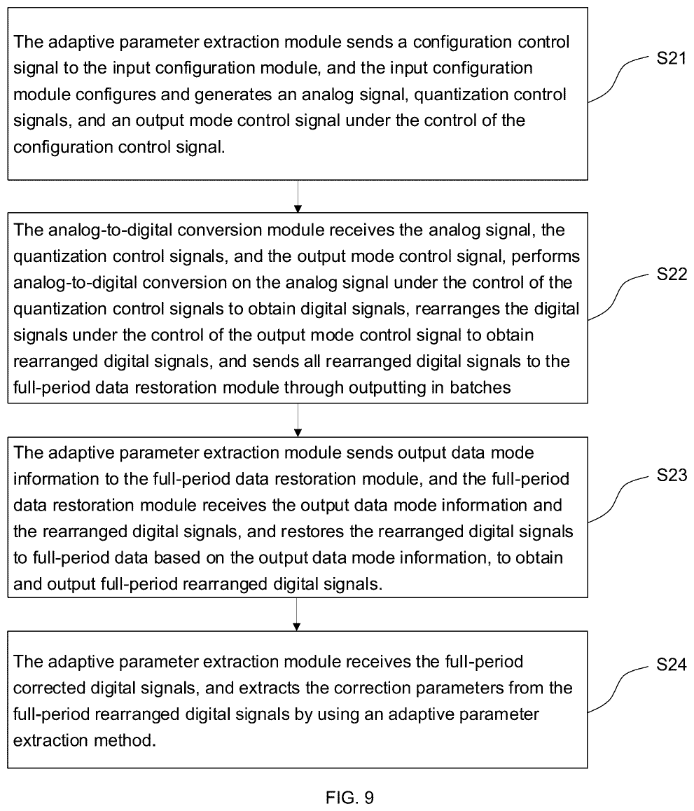

In detail, as shown in FIG. 9, S2 of extracting correction parameters of each stage of quantization circuit in the analog-to-digital converter through cooperation of the input configuration module, the data rearrangement unit, the full-period data restoration module, and the adaptive parameter extraction module further includes:
S21: The adaptive parameter extraction module sends a configuration control signal to the input configuration module, and the input configuration module configures and generates an analog signal, quantization control signals, and an output mode control signal under the control of the configuration control signal.
S22: The analog-to-digital conversion module receives the analog signal, the quantization control signals, and the output mode control signal, performs analog-to-digital conversion on the analog signal under the control of the quantization control signals to obtain digital signals, rearranges the digital signals under the control of the output mode control signal to obtain rearranged digital signals, and sends all rearranged digital signals to the full-period data restoration module through outputting in batches.
S23: The adaptive parameter extraction module sends output data mode information to the full-period data restoration module, and the full-period data restoration module receives the output data mode information and the rearranged digital signals, and restores the rearranged digital signals to full-period data based on the output data mode information, to obtain and output full-period rearranged digital signals.
S24: The adaptive parameter extraction module receives the full-period rearranged digital signals, and extracts the correction parameters from the full-period rearranged digital signals by using an adaptive parameter extraction method.

The adaptive parameter extraction module extracts the correction parameters by using the adaptive parameter extraction method, which requires a small quantity of samples, thereby greatly reducing a computational amount of parameter extraction. S2 shows only a correction parameter extraction process for one stage of quantization circuit in the analog-to-digital converter. In the present disclosure, the correction parameters of each stage of quantization circuit in the analog-to-digital converter need to be separately extracted stage by stage. Details are not described herein.

In detail, in S3, the parameter memory is added to the analog-to-digital converter, and the parameter memory combines one-time storage and solidification storage. Solidification storage can be performed only after the correction parameters of each stage of quantization circuit in the analog-to-digital converter pass a verification test, thereby effectively improving storage efficiency.

In detail, in S4, the digital calibration unit is added to the analog-to-digital converter. In the digital calibration unit, the digital signals obtained through analog-to-digital conversion of the analog-to-digital converter are calibrated and corrected based on the correction parameters stored in the parameter memory to obtain the corrected digital signals for implementing digital calibration. The correction parameters include at least a dither correction parameter, a gain correction parameter, and a mismatch error correction parameter. Therefore, a signal-to-noise ratio of the analog-to-digital converter is effectively increased and linearity of the analog-to-digital converter is effectively improved, performance of the analog-to-digital converter is prevented from being affected by an increasingly small intrinsic gain and an increasingly large mismatch error that are caused by reduction of a process size, injected random dithers are completely eliminated, and the signal-to-noise ratio of the analog-to-digital converter is prevented from being affected by the injected random dithers. A calibration manner is digital calibration that has higher error calibration precision compared with an analog calibration manner while resolving problems of a decrease in the signal-to-noise ratio and reduction of linearity of the analog-to-digital converter that are caused by a process deviation and an insufficient component intrinsic gain.

The foregoing embodiments merely illustrate principles and effects of the present disclosure, but are not intended to limit the present disclosure. Any person skilled in the art may modify or alter the foregoing embodiments without departing from the scope of the present disclosure. Therefore, all equivalent modifications or alterations completed by a person of ordinary skill in the art should still be covered by the claims of the present disclosure.

What is claimed is:

1. A high-speed and high-precision analog-to-digital converter, comprising an input configuration module, an analog-to-digital conversion module, an adaptive parameter extraction module, and a full-period data restoration module, wherein
the adaptive parameter extraction module is configured to send a configuration control signal to the input configuration module, and the input configuration module is configured to generate an analog signal, quantization control signals, and an output mode control signal under control of the configuration control signal;
the analog-to-digital conversion module is configured to receive the analog signal, the quantization control signals and the output mode control signal and perform analog-to-digital conversion on the analog signal to obtain digital signals, and under control of the quantization control signals and the output mode control signal, the analog-to-digital conversion module is further configured to rearrange the digital signals to obtain rearranged digital signals when the high-speed and high-precision analog-to-digital converter is in a parameter extraction working mode, and configured to calibrate the digital signals based on correction parameters to obtain corrected digital signals when the high-speed and high-precision analog-to-digital converter is in a normal working mode;
the adaptive parameter extraction module is configured to send output data mode information to the full-period data restoration module, and the full-period data restoration module is configured to receive the output data mode information and the rearranged digital signals, and restore the rearranged digital signals to full-period data based on the output data mode information, to obtain and output full-period rearranged digital signals;
the adaptive parameter extraction module is configured to receive the full-period rearranged digital signals, extract the correction parameters from the full-period rearranged digital signals by using an adaptive parameter extraction method, and then send the correction parameters to a parameter memory inside the analog-to-digital converter for storage; and
the correction parameters comprise at least a dither correction parameter, a gain correction parameter, and a mismatch error correction parameter.

2. The high-speed and high-precision analog-to-digital converter according to claim 1, wherein the analog-to-digital conversion module comprises a first operation circuit, n stages of quantization circuits cascaded in sequence, n random number generation circuits, and n analog random signal generation circuits, the n random number generation circuits are connected to the n analog random signal generation circuits in a one-to-one correspondence, the random number generation circuit is configured to generate a random digital signal, and the analog random signal generation circuit is configured to perform digital-to-analog conversion on the random digital signal to obtain a random analog signal; a first input terminal of the first operation circuit is connected to the analog signal, a second input terminal of the first operation circuit is connected to a first random analog signal, an output terminal of the first operation circuit is connected to an analog input terminal of a first stage of quantization circuit, and the first operation circuit is configured to perform an additive operation on the analog signal and the first random analog signal; a feedback adjustment input terminal of the first stage of quantization circuit is connected to a second random analog signal, a control input terminal of the first stage of quantization circuit is connected to a first quantization control signal, an analog output terminal of the first stage of quantization circuit is connected to an analog input terminal of a second stage of quantization circuit, and a digital output terminal of the first stage of quantization circuit outputs a first stage of digital signal; a feedback adjustment input terminal of an i^{th} stage of quantization circuit is connected to an (i+1)^{th} random analog signal, a control input terminal of the i^{th} stage of quantization circuit is connected to an i^{th} quantization control signal, an analog output terminal of the i^{th} stage of quantization circuit is connected to an analog input terminal of an (i+1)^{th} stage of quantization circuit, and a digital output terminal of the i^{th} stage of quantization circuit outputs an i^{th} stage of digital signal; a digital output terminal of an n^{th} stage of quantization circuit outputs an n^{th} stage of digital signal; and n is an integer greater than or equal to 2, and i is an integer of 2 to n−1.

3. The high-speed and high-precision analog-to-digital converter according to claim 2, wherein a j^{th} stage of quantization circuit comprises an analog-to-digital sub-converter and a multiplication digital-to-analog converter, an analog input terminal of the analog-to-digital sub-converter serves as an analog input terminal of the j^{th} stage of quantization circuit, the analog-to-digital sub-converter is connected to an analog input signal and configured to perform analog-to-digital conversion on the analog input signal to obtain a digital output signal, and a digital output terminal of the analog-to-digital sub-converter serves as a digital output terminal of the j^{th} stage of quantization circuit; the multiplication digital-to-analog converter comprises a digital-to-analog sub-converter, a second operation circuit, and an amplifier, the digital-to-analog sub-converter is connected to the digital output signal and configured to perform digital-to-analog conversion on the digital output signal to obtain an analog output signal, a first input terminal of the second operation circuit is connected to the analog input terminal of the analog-to-digital sub-converter, a second input terminal of the second operation circuit is connected to the analog output signal, a third input terminal of the second operation circuit serves as a feedback adjustment input terminal of the j^{th} stage of quantization circuit, the third input terminal of the second operation circuit is connected to the random analog signal, an output terminal of the second operation circuit is connected to an input terminal of the amplifier, and the second operation circuit is configured to perform an operation of “the analog input signal−the analog output signal+the random analog signal”; an output terminal of the amplifier serves as an analog output terminal of the j^{th} stage of quantization circuit; and j is an integer of 1 to n−1.

4. The high-speed and high-precision analog-to-digital converter according to claim 2, wherein the n^{th} stage of quantization circuit comprises an analog-to-digital sub-converter, an analog input terminal of the analog-to-digital sub-converter serves as an analog input terminal of the n^{th} stage of quantization circuit, the analog-to-digital sub-converter is connected to an analog input signal and configured to perform analog-to-digital conversion on the analog input signal to obtain a digital output signal, and a digital output terminal of the analog-to-digital sub-converter serves as a digital output terminal of the n^{th} stage of quantization circuit.

5. The high-speed and high-precision analog-to-digital converter according to claim 3, wherein the analog-to-digital conversion module further comprises a data alignment unit, and the data alignment unit is configured to receive n random digital signals and n stages of digital signals, and perform alignment processing on a random digital signal and a digital signal of each stage of quantization circuit.

6. The high-speed and high-precision analog-to-digital converter according to claim 5, wherein the analog-to-digital conversion module further comprises a data rearrangement unit, the data rearrangement unit is connected to the output mode control signal and the aligned n random digital signals and n stages of digital signals, and the data rearrangement unit is configured to rearrange, under control of the output mode control signal when the high-speed and high-precision analog-to-digital converter is in the parameter extraction working mode, the n random digital signals and the n stages of digital signals that are obtained after one-time sampling and alignment, to obtain the rearranged digital signals, and output the rearranged digital signals in batches.

7. The high-speed and high-precision analog-to-digital converter according to claim 6, wherein the analog-to-digital conversion module further comprises a digital calibration unit, the digital calibration unit is separately connected to the data alignment unit and the parameter memory, and when the high-speed and high-precision analog-to-digital converter is in the normal working mode, the digital calibration unit is configured to calibrate and correct, based on the correction parameters stored in the parameter memory, the n random digital signals and the n stages of digital signals that are obtained after one-time sampling and alignment, to obtain the corrected digital signals.

8. The high-speed and high-precision analog-to-digital converter according to claim 7, wherein the analog-to-digital conversion module further comprises an output interface unit, and the output interface unit is separately connected to the data rearrangement unit, the digital calibration unit, and the full-period data restoration module; when the high-speed and high-precision analog-to-digital converter is in the parameter extraction working mode, the output interface unit is configured to receive the rearranged digital signals and send the rearranged digital signals to the full-period data restoration module in batches; and when the high-speed and high-precision analog-to-digital converter is in the normal working mode, the output interface unit is configured to receive the corrected digital signals and output the corrected digital signals.

9. The high-speed and high-precision analog-to-digital converter according to claim 7, wherein the parameter memory comprises:
a soft correction parameter storage unit, configured to receive and store, at one single time, the correction parameters extracted by the adaptive parameter extraction module, and send the correction parameters to the digital calibration unit for digital calibration; and
a hard correction parameter storage unit, wherein after the correction parameters output by the soft correction parameter storage unit are qualified, the correction parameters stored in the soft correction parameter storage unit are sent to the hard correction parameter storage unit and solidified, so that the correction parameters are stored in the hard correction parameter storage unit for a long time, and when a system is powered on again after being powered off, the soft correction parameter storage unit reads, at one single time, the correction parameters stored in the hard correction parameter storage unit, and outputs the correction parameters.

10. The high-speed and high-precision analog-to-digital converter according to claim 9, wherein the dither correction parameter comprises an actual weight of each random analog signal, the gain correction parameter comprises an actual gain of each stage of quantization circuit, and the mismatch error correction parameter comprises an actual weight of the digital-to-analog sub-converter in each stage of quantization circuit.

11. An analog-to-digital converter performance improvement method, comprising:
providing an analog-to-digital converter, adding a random number generation circuit and an analog random signal generation circuit to the analog-to-digital converter, generating, by using the random number generation circuit and the analog random signal generation circuit, a plurality of random analog signals, and injecting dithers into the analog-to-digital converter by using the plurality of random analog signals;
adding an input configuration module, a data rearrangement unit, a full-period data restoration module, and an adaptive parameter extraction module to the analog-to-digital converter, and extracting correction parameters of each stage of quantization circuit in the analog-to-digital converter through cooperation of the input configuration module, the data rearrangement unit, the full-period data restoration module, and the adaptive parameter extraction module;
adding a parameter memory to the analog-to-digital converter, and storing, by using the parameter memory, the correction parameters, wherein the parameter memory performs one-time storage on the correction parameters in a test extraction phase, and the parameter memory performs solidification storage on the correction parameters after a test passes; and
adding a digital calibration unit to the analog-to-digital converter, and calibrating and correcting, in the digital calibration unit based on the correction parameters stored in the parameter memory, digital signals obtained through analog-to-digital conversion of the analog-to-digital converter, to obtain corrected digital signals for implementing digital calibration, wherein
the correction parameters comprise at least a dither correction parameter, a gain correction parameter, and a mismatch error correction parameter.

12. The analog-to-digital converter performance improvement method according to claim 11, wherein extracting correction parameters of each stage of quantization circuit in the analog-to-digital converter through cooperation of the input configuration module, the data rearrangement unit, the full-period data restoration module, and the adaptive parameter extraction module comprises:
sending, by the adaptive parameter extraction module, a configuration control signal to the input configuration module, and configuring and generating, by the input configuration module, an analog signal, quantization control signals, and an output mode control signal under control of the configuration control signal;
receiving, by the analog-to-digital conversion module, the analog signal, the quantization control signals, and the output mode control signal, performing analog-to-digital conversion on the analog signal under control of the quantization control signals to obtain digital signals, rearranging the digital signals under control of the output mode control signal to obtain rearranged digital signals, and sending all rearranged digital signals to the full-period data restoration module through outputting in batches;
sending, by the adaptive parameter extraction module, output data mode information to the full-period data restoration module, and receiving, by the full-period data restoration module, the output data mode information and the rearranged digital signals, and restoring the rearranged digital signals to full-period data based on the output data mode information, to obtain and output full-period rearranged digital signals; and
receiving, by the adaptive parameter extraction module, the full-period rearranged digital signals, and extracting the correction parameters from the full-period rearranged digital signals by using an adaptive parameter extraction method.
